(19) United States
(12) Patent Application Publication
(10) Pub. No.: US 2006/0001100 A1
(43) Pub. Date: Jan. 5, 2006

(54) Method for simulating electrostatic discharge protective circuit

(75) Inventors: Masayuki Kamei, Kyoto (JP); Toshihiro Kogami, Kyoto (JP); Katsuya Arai, Kyoto (JP); Hiroaki Yabu, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/171,200

(22) Filed: Jul. 1, 2005

(30) Foreign Application Priority Data
Jul. 5, 2004 (JP) 2004-197547

(51) Int. Cl. H01L 23/62

(52) U.S. Cl. 257/355

(57) ABSTRACT

A method for simulating an electrostatic discharge protective circuit replaces an electrostatic discharge protective element having an insulated-gate field-effect transistor having a source and a drain with an equivalent circuit including the insulated-gate field-effect transistor, a bipolar transistor, a current source, a diode, and a substrate resistance. Then, the method applies a forward bias to the source or the drain to perform a first simulation with respect to the equivalent circuit and applies a reverse bias to the source or the drain to perform a second simulation with respect to the equivalent circuit. The diode is disposed to cause, when the forward bias is applied to the source or the drain, a forward diode current to flow to the source or the drain to which the forward bias has been applied.

### CROSS-REFERENCE TO RELATED APPLICATIONS

The teachings of Japanese Patent Application JP 2004-197547, filed Jul. 5, 2004, are entirely incorporated herein by reference, inclusive of the claims, specification, and drawings.

### BACKGROUND OF THE INVENTION

The present invention relates to a method for simulating an electrostatic discharge protective circuit and, more particularly, to a method for simulating an electrostatic discharge protective circuit which employs an equivalent circuit to simulate, by using a circuit simulator, the operation and ESD (Electrostatic Discharge) resistance of an electrostatic discharge protective circuit for protecting a semiconductor integrated circuit from ESD.

With the recent trend toward the increasing miniaturization and higher function of a semiconductor integrated circuit, the area occupied by elements in an ESD protective circuit has been increasingly reduced and a discharge path therein has become more complicated. As a result, it has become difficult to maintain a sufficient amount of ESD resistance.

When an insufficient amount of ESD resistance has been proved at the stage of reliability evaluation, regressive development causes an increase in TAT (Turn Around Time) and a great loss in product development period.

To solve the problem, the simulation of the ESD resistance at design stage has been proposed and, if it is realized, an improvement in the design quality of a product model and a reduction in TAT can be expected.

As methods for evaluating the ESD resistance, there have been known several models including: a HBM (Human Body Model) the main process of which is the phenomenon wherein a charge formed in a human body is released via a device upon contact with the terminal of the device to cause a thermal breakdown in the device; an MM (Machine Model) the main process of which is the phenomenon wherein a charge formed in metal equipment is released via a device upon contact with the terminal of the device to cause an electric field breakdown in the device; and a CDM (Charging Device Model) the main process of which is the phenomenon wherein a conductor portion of a device is charged and the contact of a terminal of the device with equipment or a jig causes a discharge.

Because the ESD resistance is greatly dependant on the discharging characteristic of an ESD protective element in an ESD protective circuit, it is indispensable to model the discharging characteristic of the ESD protective element in the simulation of the ESD resistance.

FIG. 5 diagrammatically represents a current-voltage characteristic when a plus voltage serving as a reverse bias and a minus voltage serving as a forward bias each relative to the n-type drain of an n-type MOSFET (Metal-Oxide-Semiconductor Field-Effect Transistor) are applied thereto, in which the ordinate axis represents a drain current Id and the abscissa axis represents a drain voltage Vd.

As shown in FIG. 5, when the drain voltage Vd is increased gradually from 0 V in the plus direction, the current increases through a MOS region (a linear region and a saturation region) first and then through an avalanche region to reach an avalanche breakdown. When the voltage at which the avalanche breakdown occurs is reached, an npn-type parasitic bipolar transistor (hereinafter referred to as an npn-type parasitic BJT), which is a parasitic element in an n-type MOSFET, is operated (turned ON) so that a discharge eventually occurs in the parasitic BJT region. Accordingly, the current-voltage characteristic in the positive region of the drain voltage Vd exhibits a so-called snap-back characteristic.

Conversely, when the drain voltage Vd is reduced gradually from 0 V in the minus direction, a forward diode current flows in the pn junction between the n-type drain region and the p-type substrate region (p-well) in the n-type MOSFET so that a diode characteristic as shown in the diode region of FIG. 5 is observed.

When the simulation of the ESD resistance is performed with respect to an electrostatic protective circuit composed of a plurality of transistors, a method using device simulation and circuit simulation in combination or a method using only circuit simulation is used. The former method is relatively high in the accuracy of a model but has the problem that a range that can be analyzed is as narrow as several transistors and a calculation time is accordingly longer. By contrast, the latter method is capable of analyzing a circuit containing a million or more of transistors in a short period of time so that it allows the simulation of the ESD resistance by using a circuit structure reflecting the layout data of a semiconductor product. In the latter method, however, it is necessary to model an equivalent circuit which allows high-accuracy reproduction of discharging characteristics such as the snap-back characteristic and a diode characteristic of an ESD protective element in the circuit.

Conventionally, several equivalent circuits have been proposed each for an ESD protective element to be used in a circuit simulation method for predicting the ESD resistance (See, e.g., Japanese Laid-Open Patent Publication Nos. 2001-339052 and 2004-079952).

A description will be given herein below to a method for simulating an ESD protective circuit using a conventional equivalent circuit.

FIG. 6 shows the conventional equivalent circuit for the ESD protective element which is used in the method for simulating an ESD protective circuit. As the ESD protective element, an n-type MOSFET is used herein.

A conventional equivalent circuit 100 for the ESD protective element has: an n-type MOSFET 101; an npn-type parasitic BJT 102 as a parasitic element in the n-type MOSFET 101; a current source 103; and a substrate resistance 104.

The n-type MOSFET 101 is composed of: an n-type source S connected to a source terminal 105; an n-type drain D connected to a drain terminal 106; and a gate G connected to a gate terminal 107.

The npn-type parasitic BJT 102 is composed of: an n-type emitter E connected to the source terminal 105; an n-type collector C connected to the drain terminal 106; and a p-type base B connected to a substrate terminal 108 via the substrate resistance 104.

The current source 103 is disposed to have an input terminal connected to the n-type collector C (equivalent to the drain D of the n-type MOSFET 101) of the npn-type parasitic BJT 102 and an output terminal connected to the p-type base B of the npn-type parasitic BJT 102 such that a current flows from the collector C to the base B.

A description will be given herein below to a simulation operation performed with respect to the conventional equivalent circuit for the ESD protective element in comparison with the operation of a real ESD protective element.

In the n-type MOSFET in the real ESD protective circuit, when an electrostatic discharge (hereinafter referred to as a surge) in a direction reverse to the drain region is applied, an impact ionization current flows. Specifically, when the surge reverse to the drain region, i.e., a plus voltage is applied thereto in the state in which the voltage applied to each of the substrate region and the source region is 0 V and a plus voltage is applied to the gate electrode, electrons flowing from the source region to the drain region cause the phenomenon of impact ionization due to an intense electric field generated in a depletion layer which is formed at the interface between the drain region and the substrate region. As a result, an impact ionization current flows from the drain region to the substrate region.

Accordingly, the conventional equivalent circuit 100 is so constituted as to equivalently reflect the impact ionization current resulting from the phenomenon of impact ionization by disposing the current source 103 between the n-type collector C and the p-type base B in the npn-type parasitic BJT 102 and thereby causing a current Ia to flow from the collector C to the base B.

When simulation is performed by using the equivalent circuit 100 and applying the plus voltage to the drain terminal 106, a voltage at the drain terminal 106 increases to cause the current Ia corresponding to the impact ionization current to flow from the collector C to the base B via the current source 103. Consequently, a voltage drop resulting from the substrate resistance 104 increases a potential at the p-type base B so that the pn junction between the p-type base B and the n-type emitter E (equivalent to the n-type source S) is forwardly biased. As a result, the npn-type parasitic BJT 102 is brought into the ON state so that a discharge occurs, while exhibiting the snap-back characteristic.

FIG. 7 shows a current-voltage characteristic obtained by circuit simulation using the conventional equivalent circuit for the ESD protective element and a current-voltage characteristic obtained by actually measuring the real ESD protective element, wherein the ordinate axis represents a drain current Id and an abscissa axis represents a drain voltage Vd.

From FIG. 7, it can be seen that, when a plus voltage serving as a reverse bias relative to the n-type drain D is applied thereto, the result of the simulation coincides well with the result of the actual measurement.

### SUMMARY OF THE INVENTION

In accordance with the circuit simulation method using the conventional equivalent circuit for the ESD protective circuit, however, a large difference is observed between the result of the simulation and the result of the actual measurement when the minus voltage serving as the forward bias relative to the n-type drain D is applied thereto, as shown in FIG. 7.

Specifically, when the minus voltage serving as the forward bias relative to the drain terminal 106 is applied thereto in the case of performing the simulation using the equivalent circuit 100 shown in FIG. 6, the potential at the drain terminal 106 becomes lower than that at the substrate terminal 108 so that a diode current 1b which is forward relative to the pn junction between the base B and collector C of the npn-type parasitic BJT 102 flows. At this time, the diode current 1b flows via the substrate resistance 104 disposed between the substrate terminal 108 and the base B of the npn-type parasitic BJT 102. Consequently, the simulation is performed in the state in which an output resistance (ON resistance) higher than in an actual situation is interposed so that the result of the simulation indicated by the solid line with a small gradient shown in FIG. 7 is obtained.

In the real ESD protective element, by contrast, a forward diode current flows from the substrate region to the drain region without interposition of a high substrate resistance when the minus voltage serving as the forward bias relative to the drain region is applied thereto so that the result indicated by the actually measured values (the marks 0) with a large gradient shown in FIG. 7 is obtained.

Thus, the simulation method using the conventional equivalent circuit for the ESD protective element cannot reproduce the characteristic of the real ESD protective element over the entire region of the polarities of the applied voltage (i.e., the forward bias and the reverse bias). Accordingly, the circuit simulation using the conventional equivalent circuit for the ESD protective element encounters the problem that the result of the simulation does not coincide with the values actually measured for evaluation when the forward bias relative to the drain or source of the equivalent circuit for the ESD protective element is applied thereto.

It is therefore an object of the present invention to solve the conventional problem and thereby provide a method for simulating an ESD protective circuit using an equivalent circuit for an ESD protective element which allows high-accuracy simulation to be performed either with a forward bias or a reverse bias.

To attain the foregoing object, the present invention provides a method for simulating an electrostatic discharge protective circuit having an insulated-gate field-effect transistor such that a diode is disposed in an equivalent circuit to cause a forward diode current to flow to the source or drain to which a forward bias has been applied.

Specifically, the method for simulating an electrostatic discharge protective circuit according to the present invention comprises the steps of: replacing an electrostatic discharge protective element having an insulated-gate field-effect transistor having a source and a drain with an equivalent circuit including the insulated-gate field-effect transistor, a bipolar transistor, a current source, a diode, and a substrate resistance; applying a forward bias to the source or the drain to perform a first simulation with respect to the equivalent circuit; and applying a reverse bias to the source or the drain to perform a second simulation with respect to the equivalent circuit, wherein the diode is disposed to cause, when the forward bias is applied to the source or the drain, a forward diode current to flow to the source or drain to which the forward bias has been applied.

The method for simulating an electrostatic discharge protective circuit according to the present invention allows a high-accuracy characteristic close to an actually measured current-voltage characteristic to be reproduced in the result of simulating electrostatic discharge resistance when the forward bias is applied to the equivalent circuit without showing an excessively high output resistance (ON resistance). Therefore, even when the simulation process includes a potential state which applies a forward bias to the electrostatic discharge protective element, electrostatic discharge resistance can be predicted with high accuracy.

In the method for simulating an electrostatic discharge protective circuit according to the present invention, the step of the replacement with the equivalent circuit preferably includes: composing the bipolar transistor of an emitter equivalent to the source, a collector equivalent to the drain, and a base connected to a substrate terminal via the substrate resistance; disposing the current source to cause a current to flow from the collector to the base; and disposing the diode to cause a forward diode current to flow between the substrate terminal and the drain and the step of performing the first simulation preferably includes: applying the forward bias to the drain.

Alternatively, in the method for simulating an electrostatic discharge protective circuit according to the present invention, the step of the replacement with the equivalent circuit preferably includes: composing the bipolar transistor of an emitter equivalent to the source, a collector equivalent to the drain, and a base connected to a substrate terminal via the substrate resistance; disposing the current source to cause a current to flow from the emitter to the base; and disposing the diode to cause a forward diode current to flow between the substrate terminal and the source and the step of performing the first simulation preferably includes applying the forward bias to the source.

Alternatively, in the method for simulating an electrostatic discharge protective circuit according to the present invention, the step of the replacement with the equivalent circuit preferably includes: using first and second current sources as the current source and using first and second diodes as the diode; composing the bipolar transistor of an emitter equivalent to the source, a collector equivalent to the drain, and a base connected to a substrate terminal via the substrate resistance; disposing the first current source to cause a current to flow from the collector to the base; disposing the second current to cause a current to flow from the emitter to the base; disposing the first diode to cause a forward diode current to flow between the substrate terminal and the drain; and disposing the second diode to cause a forward diode current to flow between the substrate terminal and the source.

### BRIEF DESCRIPTION OF THE DRAWINGS

FIG. 1 is a circuit diagram showing an equivalent circuit for an ESD protective element according to a first embodiment of the present invention;

FIG. 2 is a graph showing a current-voltage characteristic obtained by circuit simulation using the equivalent circuit for the ESD protective element according to the first embodiment and a current-voltage characteristic obtained by actually measuring a real ESD protective element;

FIG. 3 is a circuit diagram showing an equivalent circuit for an ESD protective element according to a second embodiment of the present invention;

FIG. 4 is a circuit diagram showing an equivalent circuit for an ESD protective element according to a third embodiment of the present invention;

FIG. 5 is a graph diagrammatically showing a current-voltage characteristic when a plus voltage serving as a reverse bias and a minus voltage serving as a forward voltage each relative to the n-type drain of an n-type MOSFET are applied thereto;

FIG. 6 is a circuit diagram showing a conventional equivalent circuit for an ESD protective element; and

FIG. 7 is a graph showing a current-voltage characteristic obtained by circuit simulation using the conventional equivalent circuit for the ESD protective element and a current-voltage characteristic obtained by actually measuring a real ESD protective element.

### DESCRIPTION OF THE PREFERRED EMBODIMENTS

### Embodiment 1

A first embodiment of the present invention will be described with reference to the drawings.

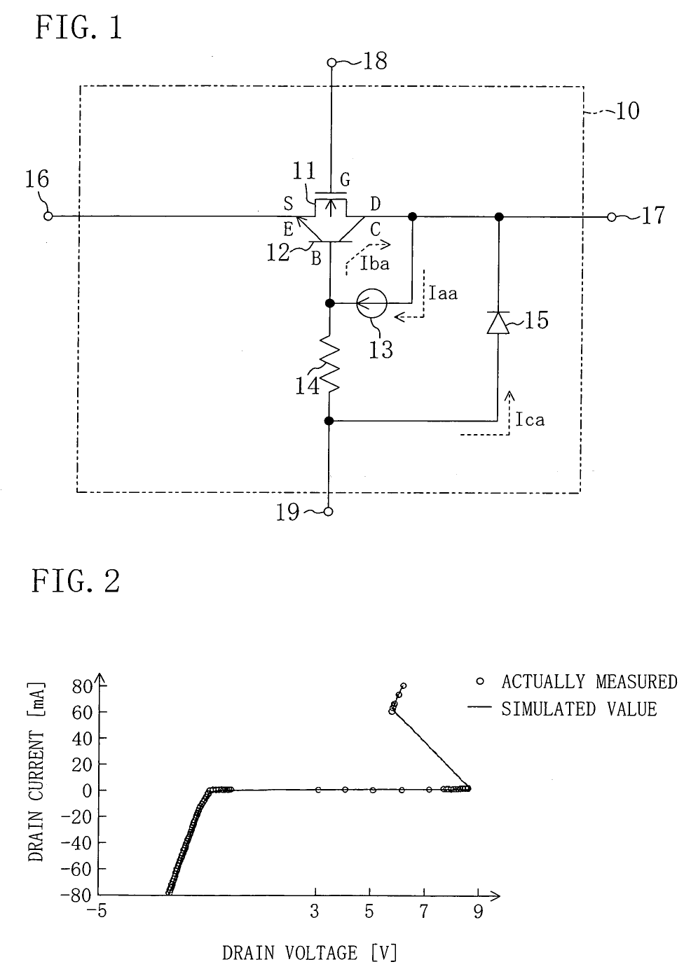

FIG. 1 shows an equivalent circuit for an ESD protective element according to the first embodiment. For the ESD protective element, an n-type MOSFET is used herein.

An equivalent circuit 10 for the ESD protective element according to the first embodiment has: an n-type MOSFET 11; an npn-type parasitic bipolar transistor (BJT) 12 which is a parasitic element in the n-type MOSFET 11; a current source 13; a substrate resistance 14; and a parasitic diode 15.

The n-type MOSFET 11 is composed of: an n-type source S connected to a source terminal 16; an n-type drain D connected to a drain terminal 17; and a gate G connected to a gate terminal 18.

The npn-type parasitic BJT 12 is composed of: an n-type emitter E connected to the source terminal 16; an n-type collector C connected to the drain terminal 17; and a p-type base B connected to a substrate terminal 19 via a substrate resistance 19.

The current source 13 is disposed to have an input terminal connected to the n-type collector C (equivalent to the drain D of the n-type MOSFET 11) of the npn-type parasitic BJT 12 and an output terminal connected to the p-type base B of the npn-type parasitic BJT 12 such that a current flows from the collector C to the base B.

The parasitic diode 15 is disposed to have a cathode connected to the drain terminal 17 and an anode connected to the substrate terminal 19 such that a forward diode current flows from the substrate terminal 19 to the drain terminal 17.

A description will be given herein below to a simulation operation performed with respect to the equivalent circuit for the ESD protective element according to the first embodiment in comparison with the operation of a real ESD protective element.

In the n-type MOSFET in the real ESD protective circuit, when a reverse surge relative to the drain region, i.e., a plus voltage is applied thereto, an impact ionization current flows from the drain region to the substrate region, as described above.

Accordingly, the equivalent circuit 10 of the first embodiment is so constituted as to equivalently reflect the impact ionization current resulting from the phenomenon of impact ionization by disposing the current source 13 between the n-type collector C and the p-type base B in the npn-type parasitic BJT 12 to cause a current Iaa to flow from the collector C to the base B.

When simulation is performed by using the equivalent circuit 10 and applying the plus voltage to the drain terminal 17, a voltage at the drain terminal 17 increases to cause the current Iaa corresponding to the impact ionization current to flow from the collector C to the base B via the current source 13. Consequently, a voltage drop resulting from the substrate resistance 14 increases a potential at the p-type base B so that the pn junction between the p-type base B and the n-type emitter E (equivalent to the n-type source S) is forwardly biased. As a result, the npn-type parasitic BJT 12 in the equivalent circuit 10 is brought into the ON state so that a discharge occurs, while exhibiting the snap-back characteristic.

In the n-type MOSFET in the real ESD protective circuit, by contrast, a forward diode current flows when a forward surge is applied to the drain region. Specifically, when a forward surge relative to the drain region, i.e., a minus voltage is applied thereto in the state in which the voltage applied to each of the substrate region and the source region is 0 V and a plus voltage is applied to the gate electrode, a forward diode current relative to the pn junction between the substrate region and the drain region flows.

In view of this, the equivalent circuit 10 according to the first embodiment is so constituted as to cause a forward diode current Ica to flow from the substrate terminal 19 to the drain terminal 17 by disposing the parasitic diode 15 having the cathode thereof connected to the drain terminal 17 and the anode thereof connected to the substrate terminal 19 between the drain terminal 17 and the substrate terminal 19.

When simulation is performed by applying a minus voltage to the drain terminal 17, the voltage at the drain terminal 17 becomes lower than the voltage at the substrate terminal 19 so that, in addition to a forward diode current Iba flowing into the drain terminal 17 by passing through the substrate resistance 14 via the pn junction between the base B and the collector C in the npn-type parasitic BJT 12, the forward diode current Ica flows from the substrate terminal 19 into the drain terminal 17 via the parasitic diode 15. At this time, since the substrate resistance 14 is high, the diode current Ica flows in a larger amount than the diode current Iba. Accordingly, the current-voltage characteristic in the equivalent circuit 10 is determined by the diode current Ica flowing into the drain terminal 17 via the parasitic diode 15.

FIG. 2 shows a current-voltage characteristic obtained by circuit simulation using the equivalent circuit for the ESD protective element according to the first embodiment and a current-voltage characteristic obtained by actually measuring the real ESD protective element. The drawing shows the result of simulating the current-voltage characteristic when a forward bias (minus voltage) and a reverse bias (plus voltage) are applied to the drain terminal 17 in the state in which the voltage applied to each of the source terminal 16 and the substrate terminal 19 is 0 V and a plus voltage is applied to the gate terminal 18 in the equivalent circuit for the ESD protective element shown in FIG. 1 and the result of actually measuring the current-voltage characteristic. For the equivalent circuit 10 for the ESD protective element, respective equivalent circuits generated by SPICE (Simulation Program with Integrated Circuit Emphasis) are used as the n-type MOSFET 11, the npn-type parasitic BJT 12, and the parasitic diode 15. The channel length L and channel width W of the n-type MOSFET 11 are set to 0.4 μm and 10 μm, respectively, and the substrate resistance 14 is set to 193 Ω in accordance with the actually measured value.

As shown in FIG. 2, the result of the simulation represented by the solid line coincides extremely well with the result of the actual measurement (the marks o) in each of the snap-back characteristic when the reverse bias (plus voltage) was applied to the drain terminal 17 and the forward diode characteristic when the forward bias (minus voltage) was applied to the drain terminal 17.

By thus performing circuit simulation using the equivalent circuit 10 for the ESD protective element according to the first embodiment, a high-accuracy simulation result which is extremely close to an actually measured current-voltage characteristic can be obtained. This allows high-accuracy prediction of ESD resistance through the simulation of an ESD protective circuit.

### Embodiment 2

A second embodiment of the present invention will be described with reference to the drawings.

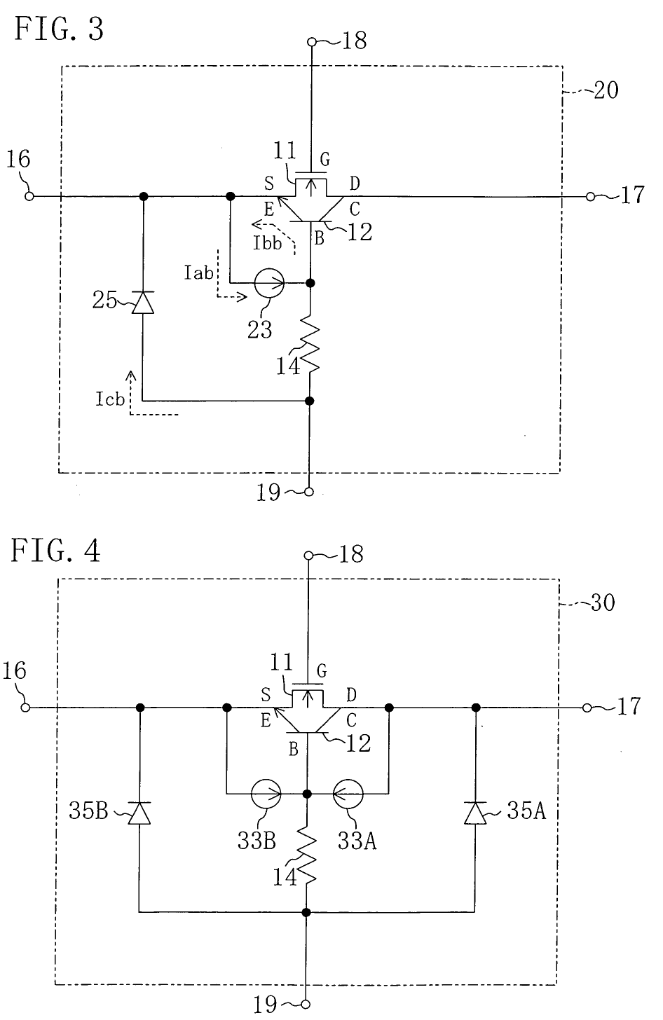

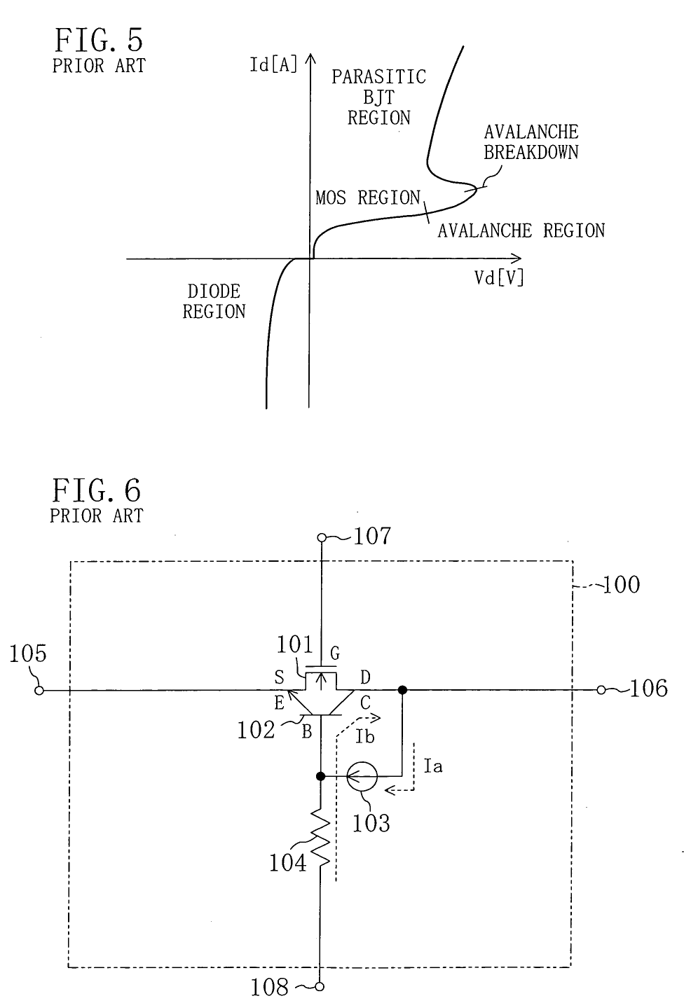

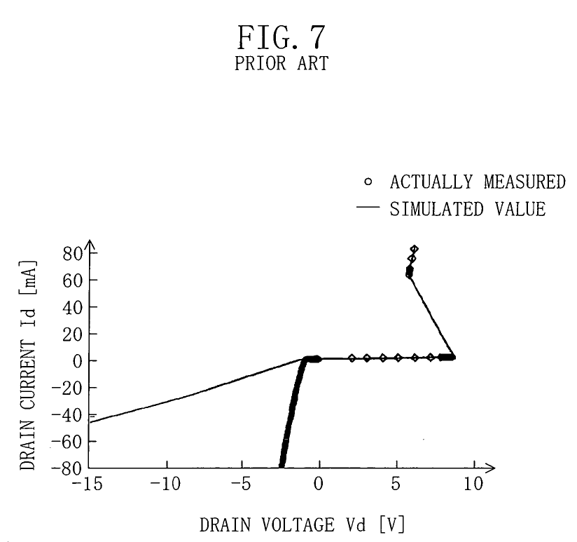

FIG. 3 shows an equivalent circuit for an ESD protective element according to the second embodiment. For the ESD protective element, an n-type MOSFET is used herein. The description of the components shown in FIG. 3 which are the same as those shown in FIG. 1 will be omitted by retaining the same reference numerals.

A current source 23 in an equivalent circuit 20 for the ESD protective element according to the second embodiment is disposed to have an input terminal connected to the n-type emitter E (equivalent to the source S of the n-type MOSFET 11) of the npn-type parasitic BJT 12 and an output terminal connected to the p-type base B of the npn-type parasitic BJT 12 such that a current flows from the emitter E to the base B.

A parasitic diode 25 is disposed to have a cathode connected to the source terminal 16 and an anode connected to the substrate terminal 19 such that a forward diode current flows from the substrate terminal 19 to the source terminal 16.

A description will be given next to a simulation operation performed with respect to the equivalent circuit for the ESD protective element according to the second embodiment in comparison with the operation of a real ESD protective element.

In the n-type MOSFET in the real ESD protective circuit, when a reverse surge relative to the source region is applied thereto, an impact ionization current flows. Specifically, when the reverse surge relative to the source region, i.e., a plus voltage is applied thereto in the state in which the voltage applied to each of the substrate region and the drain region is 0 V and a plus voltage is applied to the gate electrode, electrons flowing from the drain region to the source region cause the phenomenon of impact ionization due to an intense electric field generated in a depletion layer which is formed at the interface between the source region and the substrate region. As a result, an impact ionization current flows from the source region to the substrate region.

Accordingly, the equivalent circuit 20 of the second embodiment is so constituted as to equivalently reflect the impact ionization current resulting from the phenomenon of impact ionization by disposing the current source 23 between the n-type emitter E and the p-type base B in the npn-type parasitic BJT 12 to cause a current Iab to flow from the emitter E toward the base.

When simulation is performed by using the equivalent circuit 20 and applying the plus voltage to the source terminal 16, a voltage at the source terminal 16 increases to cause the current Iab corresponding to the impact ionization current to flow from the emitter E to the base B via the current source 23. Consequently, a voltage drop resulting from the substrate resistance 14 increases a potential at the p-type base B so that the pn junction between the p-type base B and the n-type emitter E (equivalent to the n-type drain D) is forwardly biased. As a result, the npn-type parasitic BJT 12 is brought into the ON state so that a discharge occurs, while exhibiting the snap-back characteristic.

In the n-type MOSFET in the real ESD protective circuit, by contrast, a forward diode current flows when a forward surge is applied to the source region. Specifically, when a forward surge relative to the source region, i.e., a minus voltage is applied thereto in the state in which the voltage applied to each of the substrate region and the drain region is 0 V and a plus voltage is applied to the gate electrode, a forward diode current flows to the pn junction between the substrate region and the source region.

In view of this, the equivalent circuit 20 according to the second embodiment is so constituted as to cause a forward diode current Icb to flow from the substrate terminal 19 to the source terminal 16 by disposing the parasitic diode 25 having the cathode thereof connected to the source terminal 16 and the anode thereof connected to the substrate terminal 19 between the source terminal 16 and the substrate terminal 19.

When simulation is performed by applying a minus voltage to the source terminal 16, the voltage at the source terminal 16 becomes lower than the voltage at the substrate terminal 19 so that, in addition to a forward diode current Ibb flowing into the source terminal 16 by passing through the substrate resistance 14 via the pn junction between the base B and the emitter E in the npn-type parasitic BJT 12, the forward diode current Icb flows from the substrate terminal 19 into the source terminal 16 via the parasitic diode 25. At this time, since the substrate resistance 14 is high, the diode current Icb flows in a larger amount than the diode current Ibb. Accordingly, the current-voltage characteristic in the equivalent circuit 20 is determined by the diode current Icb flowing into the source terminal 16 via the parasitic diode 25.

As a result, the result of simulating the current-voltage characteristic when a forward bias (minus voltage) and a reverse bias (plus voltage) are applied to the source terminal 16 in the state in which the voltage applied to each of the drain terminal 17 and the substrate terminal 19 is 0 V and a plus voltage is applied to the gate terminal 18 in the equivalent circuit 20 for the ESD protective element shown in FIG. 3 coincides well with the result of the actual measurement, similarly to the result of the simulation shown in FIG. 2.

By thus performing simulation using the equivalent circuit 20 for the ESD protective element according to the second embodiment, a high-accuracy simulation result which is extremely close to an actually measured current-voltage characteristic can be obtained. This allows high-accuracy prediction of ESD resistance through the simulation of an ESD protective circuit.

### Embodiment 3

A third embodiment of the present invention will be described with reference to the drawings.

FIG. 4 shows an equivalent circuit for an ESD protective element according to the third embodiment. For the ESD protective element, an n-type MOSFET is used herein. The description of the components shown in FIG. 4 which are the same as those shown in FIG. 1 will be omitted by retaining the same reference numerals.

As shown in FIG. 4, in the third embodiment, a first current source 33A and a first parasitic diode 35A are disposed to be closer to the drain of the n-type MOSFET 11, while a second current source 33B and a second parasitic diode 35B are disposed to be closer to the source of the n-type MOSFET 11.

Specifically, the first current source 33A is disposed to have an input terminal connected to the n-type collector C (equivalent to the drain D of the n-type MOSFET 11) of the npn-type parasitic BJT 12 and an output terminal connected to the p-type base B of the npn-type parasitic BJT 12 such that a current flows from the collector C to the base B.

The second current source 33B is disposed to have an input terminal connected to the n-type emitter E (equivalent to the source S of the n-type MOSFET 11) of the npn-type parasitic BJT 12 and an output terminal connected to the p-type base B of the npn-type parasitic BJT 12 such that a current flows from the emitter E to the base B.

The first parasitic diode 35A is disposed to have a cathode connected to the drain terminal 17 and an anode connected to the substrate terminal 19 such that a forward diode current flows from the substrate terminal 19 to the drain terminal 17.

The second parasitic diode 35B is disposed to have a cathode connected to the source terminal 16 and an anode connected to the substrate terminal 19 such that a forward diode current flows from the substrate terminal 19 to the source terminal 16.

Thus, in the equivalent circuit 30 for the ESD protective element according to the third embodiment, the first and second current sources 33A and 33B and the first and second parasitic diodes 35A and 35B are disposed on both sides of the source terminal 16 and the drain terminal 17, respectively, so that a circuit structure on the side with the source terminal 16 and a circuit structure on the side with the drain terminal 17 are electrically symmetric. Accordingly, it becomes possible to perform the simulation of an ESD protective circuit without distinguishing between the source terminal 16 and the drain terminal 17.

In addition, when simulation is performed by using the equivalent circuit 30 for the ESD protective element according to the third embodiment, the result of the simulation coincides well with the result of the actual measurement in the same manner as in the first and second embodiments.

By performing simulation using the equivalent circuit 30 for the ESD protective element according to the third embodiment, therefore, a high-accuracy simulation result which is extremely close to an actually measured current-voltage characteristic can be obtained. This allows high-accuracy prediction of ESD resistance through the simulation of an ESD protective circuit.

Although each of the first to third embodiments has shown the equivalent circuit for the ESD protective element in the case where the n-type MOSFET is used, the ESD resistance can also be predicted with high accuracy through the simulation of the ESD protective circuit even if the equivalent circuit for the ESD protective element is constituted by using a similar device, such as a p-type MOSFET or an n-type MISFET, instead of the n-type MOSFET.

In each of the equivalent circuits 10, 20, and 30, the substrate resistance 14 is not necessarily composed of one resistor element. The substrate resistance 14 may also be composed of a plurality of resistor elements connected in series or parallel and the resistance value of each of the resistor elements may be either variable or invariable.

Although each of the first to third embodiments has described the state in which the plus voltage is applied to the gate electrode, the present invention is not limited thereto. A zero voltage or a minus voltage may also be applied to the gate electrode.

In the case where simulation is performed with respect to an ESD protective circuit composed of a plurality of ESD protective elements, it is possible to predict the ESD resistance of the ESD protective circuit by entirely or partly converting the protective circuit to a net list based on layout data for CAD (Computer Aided Design) and incorporating the plurality of ESD protective elements in the net list resulting from the conversion.

As described above, the present invention has the effect of allowing high-accuracy simulation to be performed either with the forward bias or the reverse bias and is useful for a method for simulating an ESD protective circuit using an equivalent circuit for an ESD protective element or the like.

What is claimed is:

1. A method for simulating an electrostatic discharge protective circuit, the method comprising the steps of:
replacing an electrostatic discharge protective element having an insulated-gate field-effect transistor having a source and a drain with an equivalent circuit including the insulated-gate field-effect transistor, a bipolar transistor, a current source, a diode, and a substrate resistance;
applying a forward bias to the source or the drain to perform a first simulation with respect to the equivalent circuit; and
applying a reverse bias to the source or the drain to perform a second simulation with respect to the equivalent circuit, wherein
the diode is disposed to cause, when the forward bias is applied to the source or the drain, a forward diode current to flow to the source or drain to which the forward bias has been applied.

2. The method of claim 1, wherein
the step of the replacement with the equivalent circuit includes:
composing the bipolar transistor of an emitter equivalent to the source, a collector equivalent to the drain, and a base connected to a substrate terminal via the substrate resistance;
disposing the current source to cause a current to flow from the collector to the base; and
disposing the diode to cause a forward diode current to flow between the substrate terminal and the drain and the step of performing the first simulation includes:
applying the forward bias to the drain.

3. The method of claim 1, wherein
the step of the replacement with the equivalent circuit includes:
composing the bipolar transistor of an emitter equivalent to the source, a collector equivalent to the drain, and a base connected to a substrate terminal via the substrate resistance;
disposing the current source to cause a current to flow from the emitter to the base; and
disposing the diode to cause a forward diode current to flow between the substrate terminal and the source and the step of performing the first simulation includes applying the forward bias to the source.

4. The method of claim 1, wherein
the step of the replacement with the equivalent circuit includes:
using first and second current sources as the current source and using first and second diodes as the diode;
composing the bipolar transistor of an emitter equivalent to the source, a collector equivalent to the drain, and a base connected to a substrate terminal via the substrate resistance;
disposing the first current source to cause a current to flow from the collector to the base;
disposing the second current to cause a current to flow from the emitter to the base;
disposing the first diode to cause a forward diode current to flow between the substrate terminal and the drain; and
disposing the second diode to cause a forward diode current to flow between the substrate terminal and the source.
